(19) United States
(12) Patent Application Publication
(10) Pub. No.: US 2012/0248450 A1
(43) Pub. Date: Oct. 4, 2012

(54) ACTIVE MATRIX SUBSTRATE AND METHOD FOR PRODUCING SAME

(75) Inventors: Takeshi Yaneda, Osaka-shi (JP); Hiromitsu Katsui, Osaka-shi (JP); Wataru Nakamura, Osaka-shi (JP)

(73) Assignee: SHARP KABUSHIKI KAISHA, Osaka-shi, Osaka (JP)

(21) Appl. No.: 13/513,643

(22) PCT Filed: Nov. 2, 2010
(86) PCT No.: PCT/JP2010/069456

§ 371 Date: Jun. 4, 2012

(30) Foreign Application Priority Data
Dec. 17, 2009 (JP) 2009-286425

(51) Int. Cl. H01L 29/786; H01L 21/336; H01L 21/44

(52) U.S. Cl. 257/59; 438/597; 438/158; 257/E29.273; 257/E21.409; 257/E21.476

(57) ABSTRACT

The present invention provides an active matrix substrate that is capable of reliably connecting a plurality of conductive layers that are arranged with an insulating layer therebetween. The active matrix substrate of the present invention has a first conductive layer (CS) and a second conductive layer (30), and an insulating layer (22) formed to cover the first conductive layer (CS) is provided. The first conductive layer (CS) has an end portion (CS1) formed to protrude within an opening portion (H1) formed in the insulating layer (22), and the second conductive layer (30) is provided to cover at least a part of the edge of the opening portion (H1) and to be connected directly to the end portion (CS1) of the first conductive layer (CS) within the opening portion (H1).

### TECHNICAL FIELD

The present invention relates to an active matrix substrate used for a display panel such as a liquid crystal display panel, and a method for producing the same.

### BACKGROUND ART

In recent years, for example, liquid crystal display devices are used widely for liquid crystal TVs, monitors, mobile telephones, etc. as flat panel displays having features such as thinness and light weight, compared with conventional Braun tubes. In such a liquid crystal display device, it is known that an active matrix substrate, which is provided with a plurality of source lines (data lines) and a plurality of gate lines (scanning lines) arranged in a matrix, and pixels arranged in a matrix, each having a switching element such as a thin film transistor (TFT) disposed in the vicinity of the intersection of the source line and the gate line and a pixel electrode connected to the switching element, is used for a liquid crystal panel as a display panel.

In the above-mentioned active matrix substrate, for example a gate line is connected to a gate driver via a terminal. Specifically, in a typical active matrix substrate, a gate insulating film and a protective layer are formed sequentially on a gate electrode of a thin film transistor and a gate line configured integrally with the gate electrode, and an interlayer insulating film is formed on the protective layer. Further, in the active matrix substrate, opening portions (contact holes) are provided at a contact hole portion (terminal) in the gate insulating film, the protective layer and the interlayer insulating film, thereby connecting the gate line to ITO that is to be connected to the gate driver, and thus connecting the gate line to the gate driver via the ITO.

Further, in the conventional active matrix substrate, ITO is deposited at the opening portion to bridge over the gate insulating film and the protective layer. As a result, in the conventional active matrix substrate, disconnection may occur in the ITO due to the step difference formed between the gate insulating film and the protective layer.

Therefore, in the conventional active matrix substrate, as recited below in Patent document 1 for example, a semiconductor layer is provided between the gate insulating film and the protective layer so as to improve the step coverage between the gate insulating film and the protective layer and to avoid disconnection of the ITO.

Here, the conventional active matrix substrate will be specified with reference to FIGS. 16 and 17.

FIG. 16 is a plan view for illustrating a terminal provided in a conventional active matrix substrate. FIG. 17 is a cross-sectional view taken along a line XVII-XVII in FIG. 16.

As shown in FIGS. 16 and 17, a conventional active matrix substrate 80 includes a gate line 81 formed on a substrate 80a and an ITO 82 connected to the gate line 81 via a contact hole portion. For the gate line 81, a three-layered metal film of a titanium film 84a, an aluminum film 84b and a titanium film 84c that are formed sequentially on the substrate 80a is used for example. And in this gate line 81, the titanium film 84c is connected directly to the ITO 82 at an opening portion H0 of the contact hole portion, thereby preventing occurrence of corrosion caused by a contact between the ITO 82 and the aluminum film 84b.

Further in the conventional active matrix substrate 80, a gate insulating film 85, a protective layer 86, and an interlayer insulating film 87 are formed sequentially on the titanium film 84c of the gate line 81, and the ITO 82 and the gate line 81 are insulated from each other by the gate insulating film 85, the protective layer 86 and the interlayer insulating film 87 except at a connection portion between the ITO 82 and the titanium film 84c at the opening portion H0 of the contact hole portion.

Furthermore, in the conventional active matrix substrate 80, a semiconductor layer 83 is formed between the gate insulating film 85 and the protective layer 86. This semiconductor layer 83 is formed at the same time of formation of the semiconductor layer of a thin film transistor (not shown) provided on the active matrix substrate 80. And in this conventional active matrix substrate 80, by providing the semiconductor layer 83, the step coverage between the gate insulating film 85 and the protective layer 86 is improved. And in this conventional active matrix substrate 80, it has been considered that occurrence of disconnection in the ITO 82, which is caused by the step difference between the gate insulating film 85 and the protective layer 86, can be prevented in formation of the ITO 82.

### PRIOR ART DOCUMENTS

### Patent Documents

Patent document 1: JP 3625598

### DISCLOSURE OF INVENTION

### Problem to be Solved by the Invention

However, in the above-described conventional active matrix substrate 80, the opening portion H0 of the contact hole portion is formed by etching the gate insulating film 85, the protective layer 86 and the interlayer insulating film 87 at a time. As a result, in the conventional active matrix substrate 80 as shown in FIG. 17, the respective surfaces of the gate insulating film 85, the protective layer 86 and the interlayer insulating film 87 opposite to the opening portion H0 are configured as sharp slopes to make substantially 90° with respect to the gate line 81. And thus, in the conventional active matrix substrate 80, when forming the ITO 82 by use of a sputtering method for example, the ITO 82 may not be formed suitably at a part of each of the surfaces, and it may result in disconnection in the ITO 82.

As mentioned above, in a conventional active matrix substrate, a problem may occur, i.e., a plurality of conductive layers (the gate line 81 and the ITO 82) arranged with insulating layers (the gate insulating film 85, the protective layer 86, and interlayer insulating film 87) therebetween cannot be connected reliably.

Therefore, with the foregoing in mind, it is an object of the present invention to provide an active matrix substrate where a plurality of conductive layers arranged with an insulating layer therebetween can be connected reliably, and a method for producing the same.

### Means for Solving Problem

For achieving the above-described object, an active matrix substrate according to the present invention is an active matrix substrate having a first conductive layer and a second conductive layer to be connected to the first conductive layer, and the active matrix substrate includes at least one insulating layer provided to cover the first conductive layer. The first conductive layer has an end portion protruding within an opening portion formed in the insulating layer, and the second conductive layer is provided to cover at least a part of the edge of the opening portion and to be connected directly to the end portion of the first conductive layer within the opening portion.

In the thus configured active matrix substrate, the end portion of the first conductive layer is provided to protrude within the opening portion formed in the insulating layer. Further, the second conductive layer is provided to cover at least a part of the edge of the opening portion and to be connected directly to the end portion of the first conductive layer within the opening portion. Thereby, it is possible to connect the second conductive layer to the first conductive layer while preventing occurrence of disconnection in the second conductive layer. As a result, unlike the above-mentioned conventional technique, it is possible to configure an active matrix substrate where a plurality of conductive layers arranged with an insulating layer therebetween can be connected reliably.

Further, it is possible that the above-mentioned active matrix substrate includes a thin film transistor and a pixel electrode to be connected to the thin film transistor, wherein an electrode connection line to connect a drain electrode of the thin film transistor and the pixel electrode is used as the first conductive layer, and the pixel electrode is used as the second conductive layer.

In this case, it is possible to connect reliably the electrode connection line and the pixel electrode to each other.

Further, it is possible that the above-mentioned active matrix substrate includes an auxiliary capacitance line for generating an auxiliary capacitance and a drive portion to be connected to the auxiliary capacitance line, wherein the auxiliary capacitance line is used as the first conductive layer, and an electrode member to connect the auxiliary capacitance line to the drive portion is used as the second conductive layer.

In this case, it is possible to connect reliably the auxiliary capacitance line and the electrode member to each other.

Further, it is possible that the above-mentioned active matrix substrate includes a third conductive layer to be connected to the second conductive layer, wherein the insulating layer includes a first insulating layer provided to cover the first conductive layer and a second insulating layer provided to cover the second conductive layer, the first conductive layer has an end portion protruding within an opening portion formed in the first insulating layer, the second conductive layer is provided to cover at least a part of the edge of the opening portion formed in the first insulating layer and to be connected directly to the end portion of the first conductive layer within the opening portion formed in the first insulating layer, and the third conductive layer is provided to cover at least a part of the edge of an opening portion formed in the second insulating layer and to be connected directly to the second conductive layer within the opening portion formed in the second insulating layer.

In this case, it is possible to connect the second conductive layer to the first conductive layer while preventing occurrence of disconnection in the second conductive layer and at the same time, it is possible to connect the third conductive layer to the second conductive layer while preventing occurrence of disconnection in the third conductive layer.

Further, it is possible that the above-mentioned active matrix substrate includes a thin film transistor, a gate line to be connected to a gate electrode of the thin film transistor, and a gate driver to be connected to the gate line, wherein the gate line is used as the first conductive layer, an intermediate electrode member to be connected to the gate line is used as the second conductive layer, and an electrode member to be connected to the intermediate electrode member and to the gate driver is used as the third conductive layer.

In this case, it is possible to connect reliably the gate line and the intermediate electrode member to each other and at the same time, it is possible to connect reliably the intermediate electrode member and the electrode member to each other.

Further, it is possible that the active matrix substrate includes a thin film transistor, a source line to be connected to a source electrode of the thin film transistor, and a source driver to be connected to the source line, wherein the source line is used as the first conductive layer, an intermediate electrode member to be connected to the source line is used as the second conductive layer, and an electrode member to be connected to the intermediate electrode member and to the source driver is used as the third conductor layer.

In this case, it is possible to connect reliably the source line and the intermediate electrode member to each other, and at the same time, it is possible to connect reliably the intermediate electrode member and the electrode member to each other.

A method for producing an active matrix substrate of the present invention is a method for producing an active matrix substrate having a first conductive layer and a second conductive layer to be connected to the first conductive layer. The method includes: a step of forming the first conductive layer; a step of forming an insulating layer so as to cover the first conductive layer; a step of forming an opening portion in the insulating layer by etching the insulating layer so that an end portion of the first conductive layer is exposed in the opening portion; and a step of forming a second conductive layer so as to cover at least a part of the edge of the opening portion and to be connected directly to the end portion of the first conductive layer within the opening portion.

It is possible in the above-mentioned method for producing an active matrix substrate that an opening portion is formed in the insulating layer so that the end portion of the first conductive layer is exposed in the opening portion. Subsequently, the second conductive layer is formed to cover at least a part of the edge of the opening portion and also to be connected directly to the end portion of the first conductive layer within the opening portion. Thereby, it is possible to connect the second conductive layer to the first conductive layer while preventing occurrence of disconnection in the second conductive layer. As a result, unlike the above-mentioned conventional technique, it is possible to produce an active matrix substrate where a plurality of conductive layers arranged with an insulating layer therebetween can be connected reliably to each other.

A method for producing an active matrix substrate of the present invention is a method for producing an active matrix substrate including a thin film transistor and having a first conductive layer and a second conductive layer to be connected to the first conductive layer. The method includes: a first step of forming the first conductive layer on a base material and subsequently patterning the first conductive layer, so as to form a gate electrode of the thin film transistor and a predetermined electric line; a second step of forming a first insulating layer, a first semiconductor layer and a second semiconductor layer sequentially so as to cover the gate electrode and the electric line; a third step of forming a semiconductor layer and an electrode contact layer of the thin film transistor by etching the first insulating layer, the first semiconductor layer and the second semiconductor layer and also forming an opening portion in the first insulating layer so that an end portion of the electric line is exposed in the opening portion; a fourth step of forming a second conductive layer so as to cover the semiconductor layer, the electrode contact layer and at least a part of the edge of the opening portion and to be connected directly to the end portion of the electric line within the opening portion; and a fifth step of forming a source electrode and a drain electrode of the thin film transistor by patterning the second conductive layer.

In the above-mentioned method for producing an active matrix substrate, an opening portion is formed in the first insulating layer in the third step so that the end portion of the electric line is exposed in the opening portion. Further, in the fourth step, the second conductive layer is formed to cover at least a part of the edge of the opening portion and also to be connected directly to the end portion of the electric line within the opening portion. Thereby, it is possible to connect the second conductive layer to the electric line while preventing occurrence of disconnection in the second conductive layer. As a result, unlike the above-mentioned conventional technique, it is possible to produce an active matrix substrate where a plurality of conductive layers (electric line and first conductive layer) arranged with an insulating layer therebetween can be connected reliably.

Further, it is possible in the above-mentioned method for producing an active matrix substrate that an auxiliary capacitance line for generating an auxiliary capacitance is used as the electric line, an electrode member to connect the auxiliary capacitance line and a drive portion to be connected to the auxiliary capacitance line is used as the second conductive layer, and the fourth step is performed to form a connection portion between the auxiliary capacitance line and the electrode member.

In this case, it is possible to connect reliably the auxiliary capacitance line and the electrode member to each other.

Further, it is possible that the above-mentioned method for producing an active matrix substrate, subsequent to the fifth step, further includes: a sixth step of forming a second insulating layer so as to cover the source electrode, the drain electrode and the second conductive layer; a seventh step of forming an opening portion in the second insulating layer so that a connection portion between the end portion of the electric line and the second conductive layer is exposed in the opening portion; and an eighth step of forming a third conductive layer so as to cover at least a part of the edge of the opening portion of the second insulating layer and to be connected directly to the second conductive layer within the opening portion.

In this case, in the seventh step, the opening portion is formed in the second insulating layer so that the connection portion between the end portion of the electric line and the second conductive layer is exposed in the opening portion. Further, in the eighth step, the third conductive layer is formed to cover at least a part of the edge of the opening portion of the second insulating layer and also to be connected directly to the second conductive layer within the opening portion. Thereby, it is possible to connect the third conductive layer to the second conductive layer while preventing occurrence of disconnection in the third conductive layer.

Further, it is possible in the above-mentioned method for producing an active matrix substrate that a gate line to be connected to the gate electrode of the thin film transistor is used as the electric line, an intermediate electrode member to be connected to the gate line is used as the second conductive layer, an electrode member to be connected to a gate driver and to the intermediate electrode member is used as the third conductive layer, and the eighth step may be performed to form a gate terminal for connecting the gate line and the gate driver.

In this case, it is possible to connect reliably the gate line and the intermediate electrode member to each other, and at the same time, it is possible to connect reliably the intermediate electrode member and the electrode member to each other.

Further, it is possible in the above-mentioned active matrix substrate that a source line to be connected to the source electrode of the thin film transistor is used as the electric line, an intermediate electrode member to be connected to the source line is used as the second conductive layer, an electrode member to be connected to a source driver and to the intermediate electrode member is used as the third conductive layer, and the eighth step is performed to form a source terminal for connecting the source line and the source driver.

In this case, it is possible to connect reliably the source line and the intermediate electrode member to each other, and at the same time, it is possible to connect reliably the intermediate electrode member and the electrode member to each other.

Further it is possible in the above-mentioned method for producing an active matrix substrate that an electrode connection line for connecting the drain electrode of the thin film transistor and a pixel electrode to be connected to the thin film transistor is formed by using the second conductive layer that has been formed in the fourth step, and the pixel electrode is formed by use of the third conductive layer formed in the eighth step, and the eighth step is performed to form a connection portion between the electrode connection line and the pixel electrode.

In this case, it is possible to connect reliably the electrode connection line and the pixel electrode to each other.

Further it is possible in the above-mentioned method for producing an active matrix substrate that a halftone mask having resists different from each other in the film thickness is used in the third step.

In this case, it is possible to simplify the production process and to easily shorten the time for producing the active matrix substrate.

### Effect of Invention

According to the present invention, it is possible to provide an active matrix substrate capable of connecting reliably a plurality of conductive layers arranged with an insulating layer therebetween, and a method for producing the same.

### BRIEF DESCRIPTION OF DRAWINGS

FIG. 1 is a diagram for illustrating a liquid crystal display device according to an embodiment of the present invention.

FIG. 2 is a diagram for illustrating a configuration of a liquid crystal panel shown in FIG. 1.

FIG. 3 is a magnified plan view for illustrating configurations of main components of the active matrix substrate shown in FIG. 1.

FIG. 4 is a cross-sectional view taken along a line IV-IV in FIG. 3.

FIG. 5 is a cross-sectional view taken along a line V-V in FIG. 3.

FIG. 6 is a cross-sectional view taken along a line VI-VI in FIG. 3.

FIG. 7 is a cross-sectional view taken along a line VII-VII in FIG. 3.

FIG. 8 is a cross-sectional view taken along a line VIII-VIII in FIG. 3.

FIG. 9 is a flow chart showing a series of main processes of producing main components of an active matrix substrate.

FIG. 10 includes diagrams for illustrating processes of producing a thin film transistor shown in FIG. 4. FIGS. 10A-10E illustrate a series of main production processes.

FIG. 11 includes diagrams for illustrating processes of producing a connection portion between the auxiliary capacitance line and the electrode member shown in FIG. 5. FIGS. 11A-11D illustrate a series of main production processes.

FIG. 12 includes diagrams for illustrating processes of producing a connection portion between the electrode connection line and the pixel electrode shown in FIG. 6. FIGS. 12A-12E illustrate a series of main production processes.

FIG. 13 includes diagrams for illustrating processes of producing the gate terminal shown in FIG. 7. FIGS. 13A-13E illustrate a series of main production processes.

FIG. 14 is a plan view showing a configuration of a variation of the source terminal shown in FIG. 3.

FIG. 15 is a cross-sectional view showing a configuration of another variation of the source terminal.

FIG. 16 is a plan view for illustrating a terminal provided on a conventional active matrix substrate.

FIG. 17 is a cross-sectional view taken along a line XVII-XVII in FIG. 16.

### DESCRIPTION OF THE INVENTION

Hereinafter, preferred embodiments of an active matrix substrate, a production method thereof, and a display device of the present invention will be described with reference to the drawings. In the following description, the present invention is applied to a transmission type liquid crystal display device. The dimensions of constituent members in the drawings do not faithfully reflect the actual dimensions of constituent members, dimension ratio of the respective constituent members, etc.

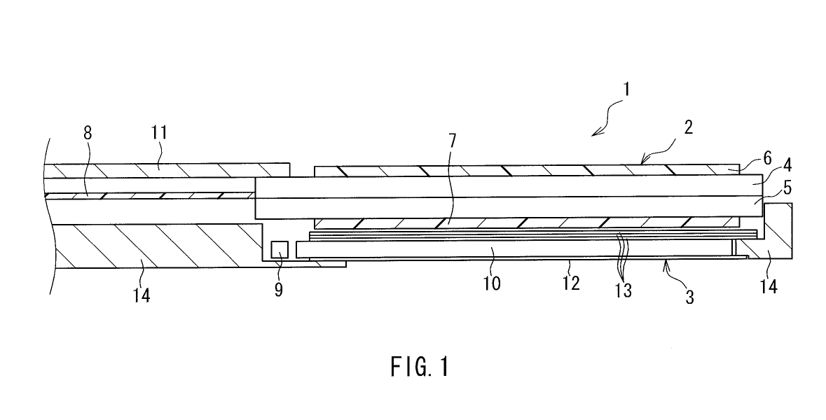

FIG. 1 is a diagram illustrating a liquid crystal display device according to one embodiment of the present invention. In FIG. 1, a liquid crystal display device 1 of the present embodiment is provided with a liquid crystal panel 2 and a backlight device 3. An upper side of the liquid crystal panel 2 in FIG. 1 is defined as a viewing side (display surface side). The backlight device 3 is arranged on a non-display surface side (lower side in FIG. 1) of the liquid crystal panel 2 and generates illumination light for illuminating the liquid crystal panel 2.

The liquid crystal panel 2 includes a color filter substrate 4 and an active matrix substrate 5 of the present invention that constitute a pair of substrates, and polarizing plates 6, 7 that are provided on outer surfaces of the color filter substrate 4 and the active matrix substrate 5, respectively. A liquid crystal layer (not shown) is sandwiched between the color filter substrate 4 and the active matrix substrate 5. The color filter substrate 4 and the active matrix substrate 5 are made of a flat plate-shaped transparent glass material or a transparent synthetic resin such as an acrylic resin. The polarizing plates 6, 7 are made of a resin film such as TAC (triacetyl cellulose) or PVA (polyvinyl alcohol). The polarizing plates 6, 7 are bonded to the corresponding color filter substrate 4 or active matrix substrate 5 so as to cover at least an effective display region of a display surface of the liquid crystal panel 2.

The active matrix substrate 5 constitutes one of the pair of substrates and includes pixel electrodes, TFTs (Thin Film Transistor), etc., that are formed between the active matrix substrate 5 and the liquid crystal layer in accordance with a plurality of pixels included in the display surface of the liquid crystal panel 2 (detailed later). Meanwhile, the color filter substrate 4 constitutes the other of the pair of substrates and includes color filters, counter electrodes, etc., that are formed between the color filter substrate 4 and the liquid crystal layer (not shown).

Further, the liquid crystal panel 2 is provided with a FPC (Flexible Printed Circuit) 8 that is connected to a control device (not shown) that performs drive control of the liquid crystal panel 2. The display surface is driven on a pixel basis by operating the liquid crystal layer on a pixel basis, whereby a desired image can be displayed on the display surface.

Note that the liquid crystal panel 2 can have any liquid crystal mode and any pixel structure. The liquid crystal panel 2 also can have any drive mode. In other words, any liquid crystal panel capable of displaying information can be used as the liquid crystal panel 2. Therefore, a detailed structure of the liquid crystal panel 2 is not illustrated in FIG. 1, and a description thereof is omitted.

The backlight device 3 includes a light-emitting diode 9 as a light source, and a light-guiding plate 10 that is arranged to be opposed to the light-emitting diode 9. Further, in the backlight device 3, the light-emitting diode 9 and the light-guiding plate 10 are sandwiched by a bezel 14 having an L-shape in cross section, with the liquid crystal panel 2 being located above the light-guiding plate 10. Further, a case 11 is mounted on the color filter substrate 4. Thus, the backlight device 3 is attached to the liquid crystal panel 2, and they are integrated as the transmission type liquid crystal display device 1 in which illumination light from the backlight device 3 enters the liquid crystal panel 2.

The light-guiding plate 10 is made of a synthetic resin such as a transparent acrylic resin and receives light from the light-emitting diode 9. A reflecting sheet 12 is disposed on a surface of the light-guiding plate 10 on a side opposite to the liquid crystal panel 2 side (opposed surface side). Further, optical sheets 13 such as a lens sheet and a diffusion sheet are provided on a surface of the light-guiding plate 10 on the liquid crystal panel 2 side (light-emitting surface side). Light from the light-emitting diode 9 that is guided inside the light-guiding plate 10 in a predetermined light-guiding direction (direction from the left side to the right side in FIG. 1) is transformed into planar illumination light having a uniform brightness, and given to the liquid crystal panel 2.

In the above description, the edge-light type backlight device 3 having the light-guiding plate 10 is used. However, the present embodiment is not limited to this, and a direct type backlight device may be used. Further, a backlight device having a light source other than light-emitting diodes such as cold cathode fluorescent tubes and hot cathode fluorescent tubes also may be used.

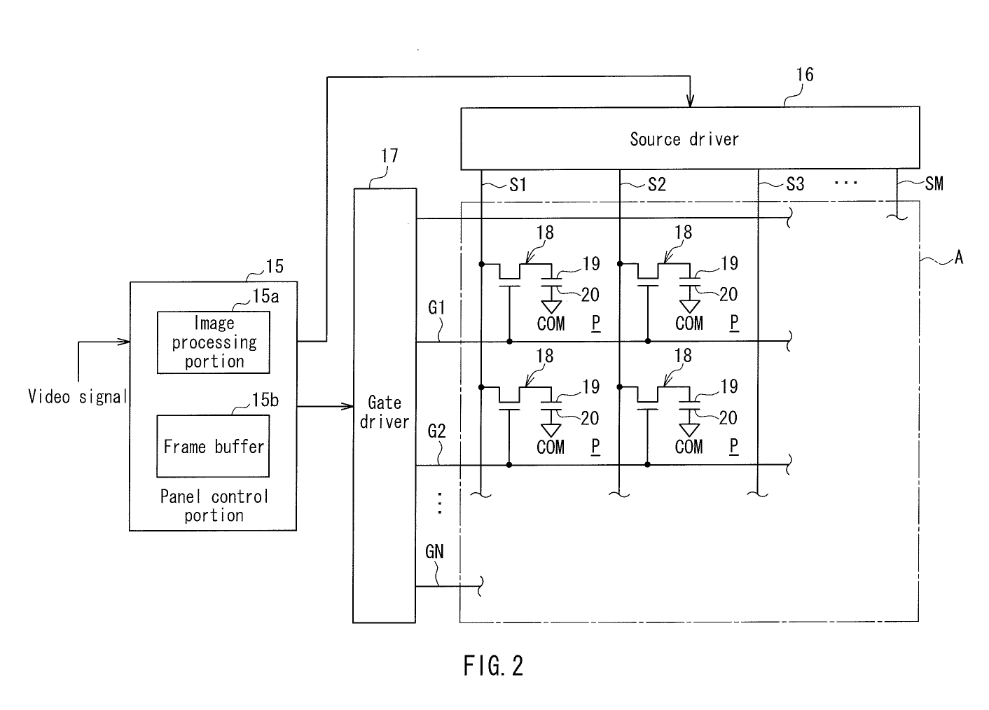

Next, the liquid crystal panel 2 of the present embodiment will be described specifically also with reference to FIG. 2.

FIG. 2 is a diagram for illustrating the configuration of the liquid crystal panel as shown in FIG. 1.

In FIG. 2, the liquid crystal display device 1 (FIG. 1) is provided with a panel control portion 15 that performs drive control of the liquid crystal panel 2 (FIG. 1) as the display portion that displays information such as characters and images, and a source driver 16 and a gate driver 17 that are operated based on instruction signals from the panel control portion 15.

The panel control portion 15 is placed in the control device and receives video signals from outside of the liquid crystal display device 1. Further, the panel control portion 15 includes an image processing portion 15a that performs predetermined image processing on input video signals so as to generate respective instruction signals to the source driver 16 and the gate driver 17, and a frame buffer 15b that can store one frame of display data contained in the input video signals. The panel control portion 15 performs drive control of the source driver 16 and the gate driver 17 in accordance with input video signals, whereby information in accordance with the video signals is displayed on the liquid crystal panel 2.

The source driver 16 and the gate driver 17 are disposed on the active matrix substrate 5. Specifically, on a surface of the active matrix substrate 5, the source driver 16 is disposed along the horizontal direction of the liquid crystal panel 2 in an outside region of an effective display area A of the liquid crystal panel 2 as a display panel. Further, the gate driver 17 is disposed along the vertical direction of the liquid crystal panel 2 in the outside region of the effective display area A on the surface of the active matrix substrate 5.

Further, the source driver 16 and the gate driver 17 are drive circuits that drive, on a pixel basis, a plurality of pixels P placed on the liquid crystal panel 2 side. The source driver 16 and the gate driver 17 respectively are connected to a plurality of source lines S1-SM (M is an integer of 2 or more; hereinafter, referred to as “S” collectively) and a plurality of gate lines G1-GN (N is an integer of 2 or more; hereinafter, referred to as “G” collectively). The source lines S and the gate lines G respectively constitute data lines and scanning lines that are arranged in a matrix so as to cross each other on a base material (not shown) made of a transparent glass material or a transparent synthetic resin contained in the active matrix substrate 5. That is, the source lines S are provided on the base material in parallel to the column direction in a matrix (longitudinal direction of the liquid crystal panel 2) and the gate lines G are provided on the base material in parallel to the row direction in a matrix (transverse direction of the liquid crystal panel 2).

Furthermore, as described below in detail, an auxiliary capacitance line for generating auxiliary capacitance is to be connected to the source driver 16, and the source driver 16 is configured to function also as a drive portion for generating the auxiliary capacitance.

Further, in the vicinity of each intersection between the source lines S and the gate lines G, a thin film transistor 18 as a switching element and the pixel P that has a pixel electrode 19 connected to the thin film transistor 18 are provided. Further, in each of the pixels P, a common electrode 20 is opposed to the pixel electrode 19, with the liquid crystal layer of the liquid crystal panel 2 being interposed therebetween. In other words, in the active matrix substrate 5, the thin film transistor 18, the pixel electrode 19 and the common electrode 20 are provided per pixel.

Further, in the active matrix substrate 5, in the respective regions partitioned in a matrix by the source lines S and the gate lines G, a plurality of regions of the pixels P are formed. The plurality of pixels P include red (R), green (G) and blue (B) pixels. The RGB pixels are arranged sequentially in parallel to the gate lines G1-GN in this order, for example. Further, the RGB pixels can display corresponding color by color filter layers (not shown) provided on the color filter substrate 4 side.

Further, in the active matrix substrate 5, the gate driver 17 sequentially outputs scanning signals (gate signals) with respect to the gate lines G1-GN so as to bring gate electrodes of the corresponding thin film transistors 18 to an ON state based on instruction signals from the image processing portion 15a. Further, the source driver 16 outputs data signals (voltage signals (gradation voltage)) in accordance with brightness (gradation) of the display image with respect to the corresponding source lines S1-SM, based on instruction signals from the image processing portion 15a.

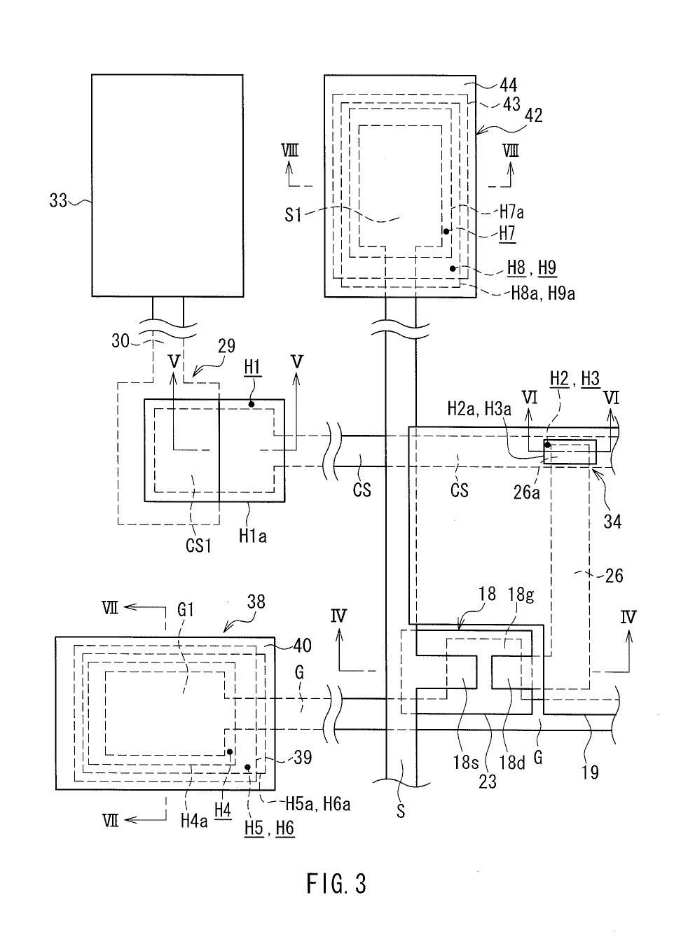

Next, configurations of main portions of the active matrix substrate 5 of the present embodiment will be described specifically also with reference to FIGS. 3 to 8.

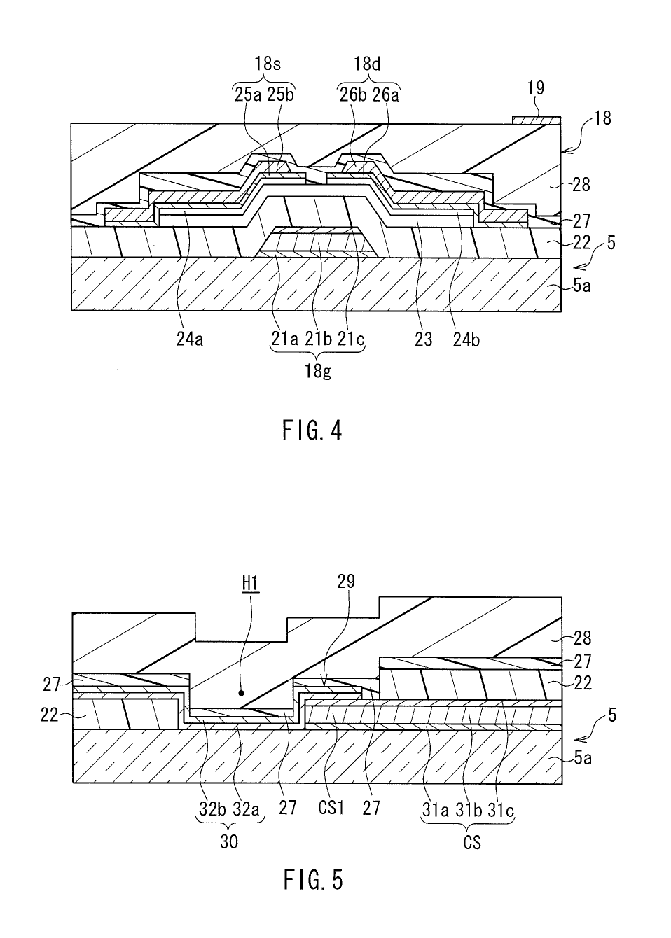

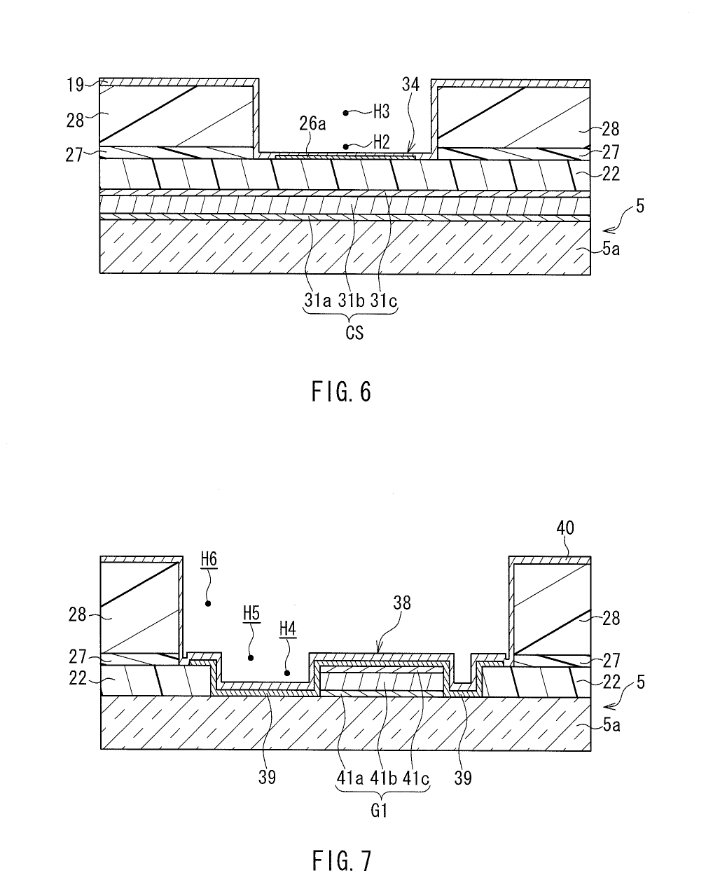

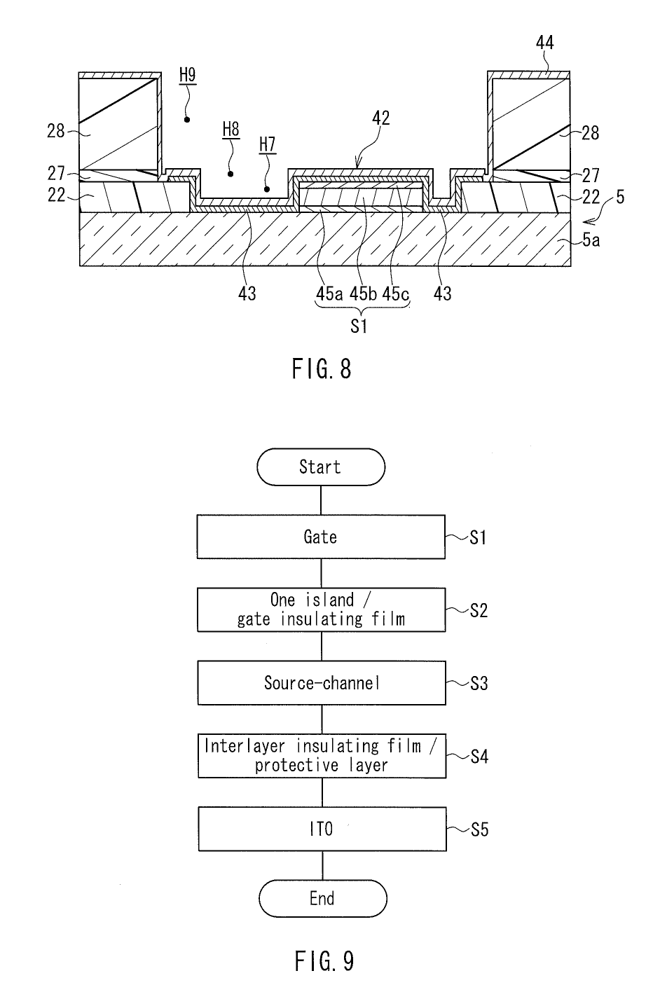

FIG. 3 is a magnified plan view for illustrating configurations of main components of the active matrix substrate shown in FIG. 1. FIG. 4 is a cross-sectional view taken along a line IV-IV in FIG. 3. FIG. 5 is a cross-sectional view taken along a line V-V in FIG. 3. FIG. 6 is a cross-sectional view taken along a line VI-VI in FIG. 3. FIG. 7 is a cross-sectional view taken along a line VII-VII in FIG. 3. And FIG. 8 is a cross-sectional view taken along a line VIII-VIII in FIG. 3.

As shown in FIG. 3, in the active matrix substrate 5 of the present embodiment, a thin film transistor 18 is provided in the vicinity of the intersection of each of the gate lines G and each of the source lines S. The thin film transistor 18 is provided with a gate electrode 18g formed integrally with the gate line G, a source electrode 18s formed integrally with the source line S, a drain electrode 18d provided to be opposed to the source electrode 18s, and an amorphous silicon layer 23 as a semiconductor layer. The gate line G and the gate electrode 18g are composed of three-layered metal films for example, and the source line S, the source electrode 18s, and the drain electrode 18d are composed of two-layered metal films for example (detailed later).

The drain electrode 18d is provided at one end portion of an electrode connection line 26 for connecting the drain electrode 18d and the pixel electrode 19. Further as detailed below, the other end portion of this electrode connection line 26 is connected to the pixel electrode 19 within opening portions H2, H3 of a contact hole portion as a connection portion 34 disposed above the auxiliary capacitance line CS.

The auxiliary capacitance line CS is a line for generating a predetermined auxiliary capacitance on a pixel basis, and it is provided in parallel with respect to the gate line G. Further, the auxiliary capacitance line CS is composed of a three-layered metal film just like the gate line G, and the end portion CS1 is connected to an electrode member 30 within the opening portion H1 of the contact hole portion as the connection portion 29. This electrode member 30 is connected to the source driver 16 as a drive portion via an end portion 33.

Further, the end portion G1 of the gate line G is connected to the gate driver 17 via a gate terminal 38. Specifically, at the gate terminal 38, the terminal G1 of the gate line G and an intermediate electrode member 39 to be connected to the gate line G are connected to each other within an opening portion H4 of the contact hole portion, and furthermore, the intermediate electrode member 39 and an electrode member 40 to be connected to the gate driver 17 are connected to each other within opening portions H5, H6 of the contact hole portion (detailed later). And the electrode member 40 is made of the same transparent conductive film (for example, ITO) as the pixel electrode 19.

Further, the end portion S1 of the source line S is connected to the source driver 16 via a source terminal 42. Specifically, at the source terminal 42, the terminal S1 of the source line S and an intermediate electrode member 43 to be connected to the source line S are connected to each other within an opening portion H7 of the contact hole portion, and furthermore, the intermediate electrode member 43 and an electrode member 44 to be connected to the source driver 16 are connected to each other within opening portions H8, H9 of the contact hole portion (detailed later). And the electrode member 44 is made of the same transparent conductive film (for example, ITO) as the pixel electrode 19.

Specifically, as shown in FIG. 4, in the thin film transistor 18, a gate electrode 18g composed of a titanium film 21a, an aluminum film 21b and a titanium film 21c for example is provided on a base material 5a of the active matrix substrate 5. Further, a gate insulating film 22 is provided to cover the gate electrode 18d, and on this gate insulating film 22, an amorphous silicon layer 23 and electrode contact layers 24a, 24b are formed. The gate insulating film 22 is made of silicon nitride (SiNx) for example. The electrode contact layers 24a, 24b are made of n+ amorphous silicon for example.

Further, for example, a source electrode 18s composed of a titanium film 25a and an aluminum film 25b is formed on the electrode contact layer 24a, and this source electrode 18s is connected to the source region of the amorphous silicon layer 23 via the electrode contact layer 24a. Meanwhile, the drain electrode 18d composed of a titanium film 26a and an aluminum film 26b for example is formed on the electrode contact layer 24b, and this drain electrode 18d is connected to the drain region of the amorphous silicon layer 23 via the electrode contact layer 24b. Further, in the amorphous silicon layer 23, a channel region is formed between the source region and the drain region. Above the channel region, electrode contact layers 24a, 24b are not formed but a predetermined gap is provided.

Further, in the thin film transistor 18, a protective layer 27 and an interlayer insulating film 28 are formed sequentially to cover the source electrode 18s and the drain electrode 18d. The protective layer 27 is made of silicon nitride (SiNx) for example. The interlayer insulating film 28 is made of a photosensitive interlayer insulating film material prepared by mixing a photosensitizer in an insulating material such as a novolac resin for example.

Further, as shown in FIG. 5, at the connection portion 29, for example an auxiliary capacitance line CS composed of a titanium film 31a, an aluminum film 31b and a titanium film 31c is provided on the base material 5a. At this connection portion 29, the auxiliary capacitance line CS constitutes the first conductive layer, and its end portion CS1 is provided to protrude within the opening portion H1 formed in the gate insulating film 22 as the first insulating layer. Further, at the connection portion 29, the electrode member 30 as the second conductive layer is connected directly to the end portion CS1 of the auxiliary capacitance line CS within the opening portion H1. This electrode member 30 is composed of a titanium film 32a and an aluminum film 32b for example, and as shown in FIG. 3, it is provided to cover at least a part of the edge H1a of the opening portion H1.

Further, as shown in FIG. 6, at the connection portion 34, the end portion of the electrode connection line 26 as the first conductive layer is provided to protrude within the opening portions H2 and H3 formed respectively in the protective layer 27 and the interlayer insulating film 28 as the insulating layers. Namely, within the opening portions H2 and H3, the titanium film 26a as the end portion of the electrode connection line 26 is formed to protrude on the gate insulating film 22. Beneath the gate insulating film 22, the auxiliary capacitance line CS is formed on the base material 5a. Further at the connection portion 34, the pixel electrode 19 as the second conductive layer is connected directly to the end portion (titanium film 26a) of the electrode connection line 26 within the opening portions H2, H3. This pixel electrode 19 is formed of ITO for example, and as shown in FIG. 3, it is provided to cover at least a part of each of the edges H2a, H3a of the opening portions H2, H3.

Further, in the present embodiment, the auxiliary capacitance is composed of the electrode connection line 26, the gate insulating film 22, and the auxiliary capacitance line CS. Alternatively, it can be composed of the pixel electrode 19, the gate insulating film 22 and the auxiliary capacitance line CS. Or it can be composed of the pixel electrode 19, the protective layer 27, the gate insulating film 22 and the auxiliary capacitance line CS. Alternatively, it can be composed of the pixel electrode 19, the interlayer insulating film 28, the protective layer 27, the gate insulating film 22 and the auxiliary capacitance line CS. In this case, the connection portion 34 is not necessarily provided above the auxiliary capacitance line CS.

Further, as shown in FIG. 7, at the above-mentioned gate terminal 38, an end portion G1 of a gate line G composed of a titanium film 41a, an aluminum film 41b, and a titanium film 41c for example is provided on the base material 5a. At this gate terminal 38, the gate line G constitutes the first conductive layer, and its end portion G1 is provided to protrude within the opening portion H4 formed in the gate insulating film 22 as the first insulating layer. Further, at the gate terminal 38, the intermediate electrode member 39 as the second conductive layer is connected directly to the end portion G1 of the gate line G within the opening portion H4. This intermediate electrode member 39 is formed of a titanium film for example, and as shown in FIG. 3, it is provided to cover at least a part of the edge H4a of the opening portion H4.

Further, at the gate terminal 38, an electrode member 40 as the third conductive layer is connected directly to the intermediate electrode member 39 within the opening portions H5 and H6 formed respectively in the protective layer 27 and the interlayer insulating film 28 as the second insulating layers. Further, this electrode member 40 is made of ITO for example, and as shown in FIG. 3, it is provided to cover at least a part of each of the edges H5a, H6a of the opening portions H5, H6.

Further, as shown in FIG. 8, at the source terminal 42, an end portion S1 of a source line S composed of a titanium film 45a, an aluminum film 45b and a titanium film 45c for example is provided on the base material 5a. At this source terminal 42, the source line S constitutes the first conductive layer, and its end portion S1 is provided to protrude within an opening portion H7 formed in the gate insulating film 22 as the first insulating layer. Namely, a gate-source switching portion (not shown) is connected to the source terminal 42, and at this gate-source switching portion, the source line S that is provided as a layer located above the gate line G on the base material 5a is provided as a layer of the same level as the gate line G on the base material 5a. And at the source terminal 42, the end portion S1 of the source terminal S is formed on the base material 5a.

Further, at the source terminal 42, an intermediate electrode member 43 as the second conductive layer is connected directly to the end portion S1 of the source line S within the opening portion H7. This intermediate electrode member 43 is composed of a titanium film for example, and as shown in FIG. 3, it is provided to cover at least a part of the edge H7a of opening portion H7.

Further, at the source terminal 42, an electrode member 44 as the third conductive layer is connected directly to the intermediate electrode member 43 within opening portions H8 and H9 formed respectively in the protective layer 27 and the interlayer insulating film 28 as the second insulating layers. Further, this electrode member 44 is made of ITO for example, and as shown in FIG. 3, it is provided to cover at least a part of each of the edges H8a, H9a of the opening portions H8, H9.

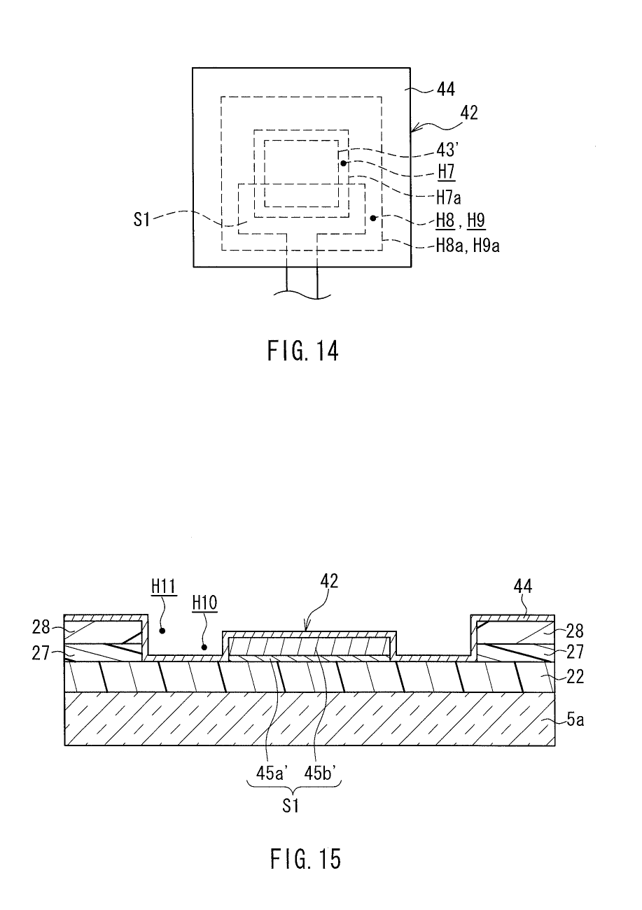

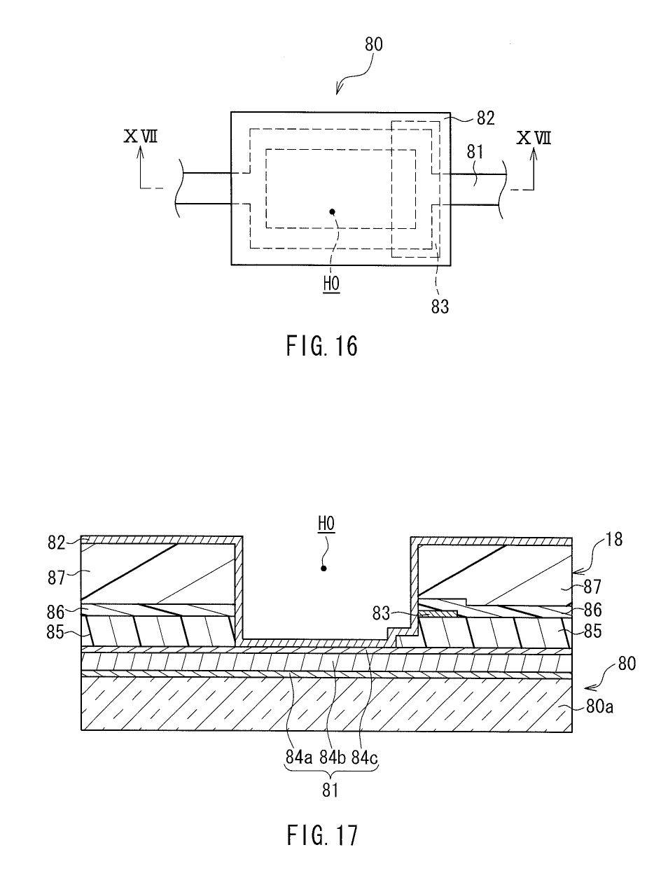

Alternatively, the source terminal 42 can be configured for example as shown in FIG. 14. In this configuration, the source terminal 42 can be configured without the above-mentioned gate-source switching portion. Specifically, in FIG. 14, at the source terminal 42, an electrode member 43′ as the first conductive layer is provided within the opening portion H7. This electrode member 43′ is composed of a three-layered metal film of a titanium film, an aluminum film and a titanium film for example. Further, with respect to this electrode member 43′, the end portion S1 of the source line S as the second conductive layer is connected within the opening portion H7. Further, this end portion S1 is composed of a two-layered metal film of a titanium film and an aluminum film for example, and it is provided to cover at least a part of the edge H7a of the opening portion H7. As mentioned below, the aluminum film of the electrode member 43′ is wet-etched selectively at the part to be exposed within the openings H8 and H9, and only the titanium films remain. Further, at this source terminal 42, the electrode member 44 as the third conductive layer is connected directly to the terminal S1 of the source line S and the electrode member 43′ within the opening portions H8 and H9 respectively formed in the protective layer 27 and the interlayer insulating film 28 as the second insulating layers. Further, this electrode member 44 is made of ITO for example, and as shown in FIG. 14, it is provided to cover at least a part of each of the edges H8a, H9a of the opening portions H8, H9.

Alternatively, the source terminal 42 can be configured for example as shown in FIG. 15. Specifically, in FIG. 15, the end portion S1 of the source line S as the first conductive layer is provided at the source terminal 42 so as to protrude within opening portions H10 and H11 formed respectively in the protective layer 27 and the interlayer insulating film 28 as the insulating layers. For the end portion S1 of the source line S, a titanium film 45a′ and a copper film 45b′ are used for example. Further, at this source terminal 42, the electrode member 44 as the second conductive layer is connected to the end portion S1 of the source line S within the opening portions H10 and H11. This electrode member 44 is made of ITO for example, and it is provided to cover at least a part of each of the edges of the opening portions H10, H11.

At the terminal 33, similarly to the source terminal 42, an intermediate electrode member and an electrode member are provided, and the electrode member 30 is connected to the source driver 16 via these intermediate electrode member and the electrode member.

Hereinafter, a method for producing main components of the active matrix substrate 5 of the above-mentioned configurations in the present embodiment will be specified with reference also to FIGS. 9-13.

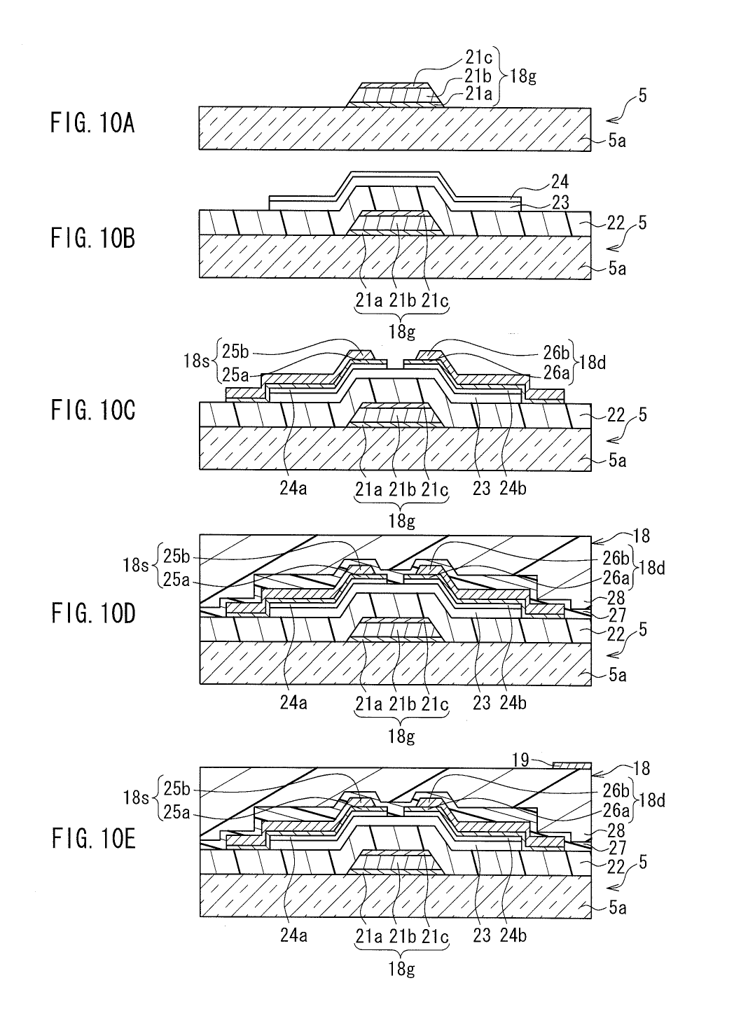

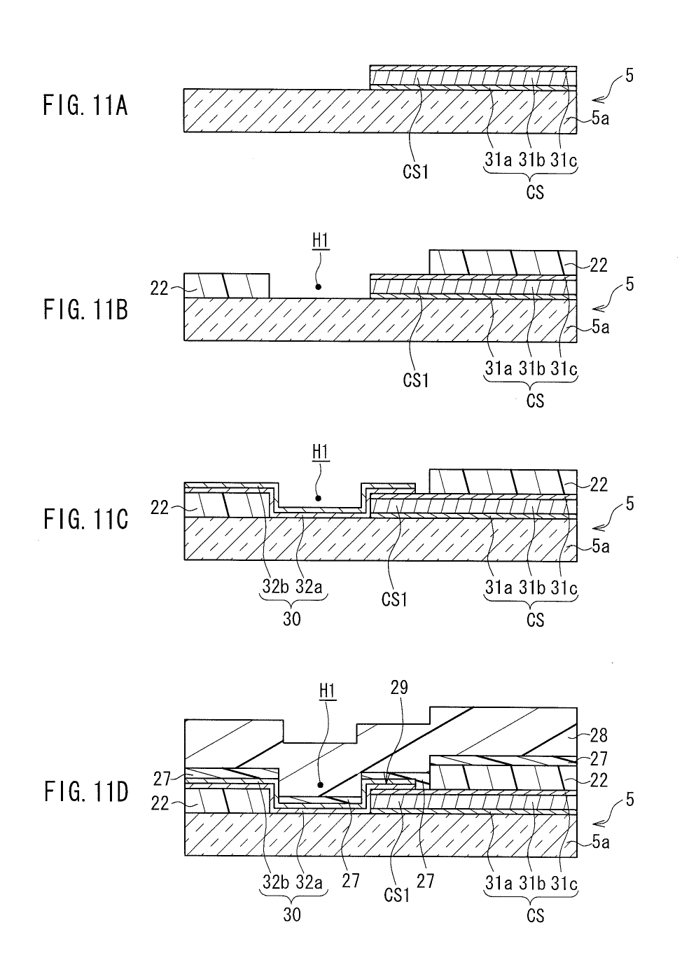

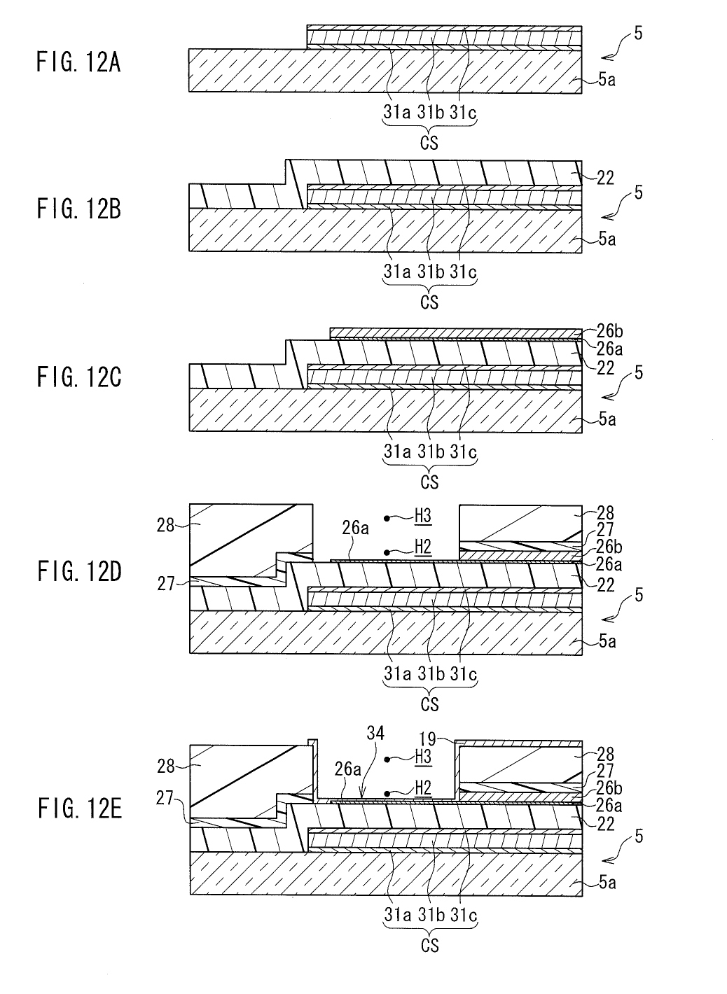

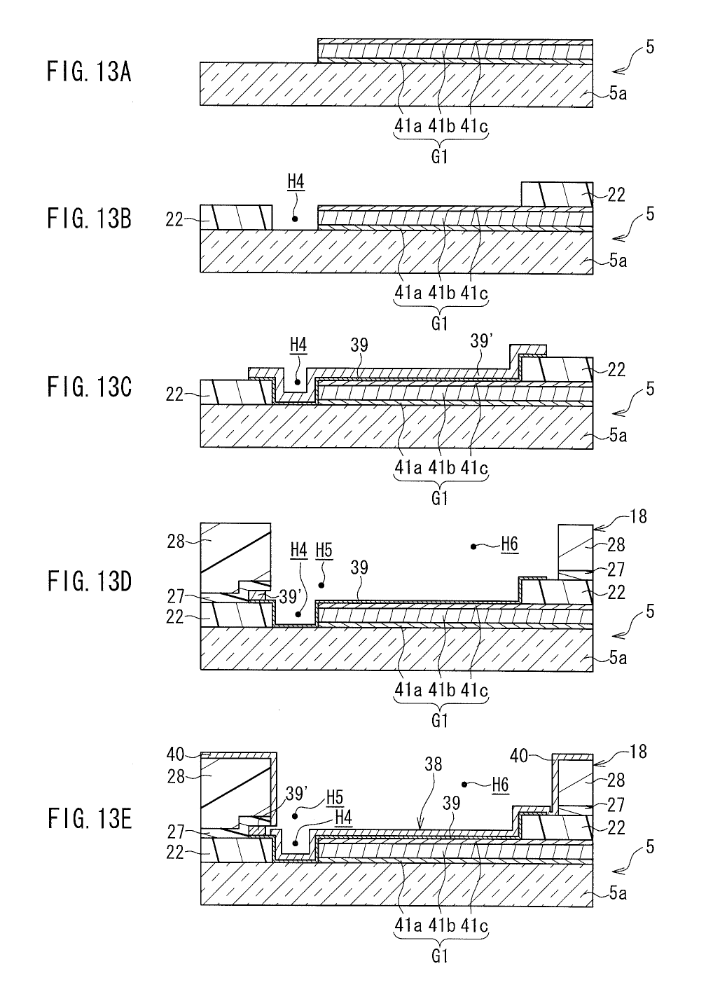

FIG. 9 is a flow chart showing main processes of producing main components of an active matrix substrate. FIG. 10 includes diagrams for illustrating processes of producing the thin film transistor as shown in FIG. 4. FIGS. 10A-10E are the diagrams for illustrating a series of main production processes. FIG. 11 includes diagrams for illustrating processes of producing a connection portion between an auxiliary capacitance line and an electrode member as shown in FIG. 5. FIGS. 11A-11D are the diagrams for illustrating a series of main production processes. FIG. 12 includes diagrams for illustrating processes of producing a connection portion between the electrode connection line and the pixel electrode as shown in FIG. 6. FIGS. 12A-12E are the diagrams for illustrating a series of main production processes. FIG. 13 includes diagrams for illustrating processes of producing the gate terminal as shown in FIG. 7. FIGS. 12A-13E are the diagrams for illustrating a series of main production processes. In the description below, explanation of the processes of forming the source terminal 42 that is formed similarly to the gate terminal 38 is omitted for avoiding duplicated explanation.

As shown in FIG. 9, in the active matrix substrate 5, the gate electrode 18g is formed first (step S1).

In a specific example as shown in FIG. 10A, a titanium film 21a, an aluminum film 21b and a titanium film 21c are deposited on a base material 5a composed of a glass substrate by a sputtering method for example, and subsequently photolithography, wet-etching, and resist-peeling irrigation are carried out for patterning, thereby forming the gate electrode 18g composed of the titanium film 21a, the aluminum film 21b and the titanium film 21c. At the same time of formation of the gate electrode 18g, as respectively shown in FIGS. 11A and 12A, an auxiliary capacitance line CS composed of a titanium film 31a, an aluminum film 31b and a titanium film 31c is formed at each of the connection portions 29 and 34 on the base material 5a. Furthermore, at the same time of formation of the gate electrode 18g, as shown in FIG. 13A, an end portion G1 of the gate line G composed of a titanium film 41a, an aluminum film 41b and a titanium film 41c is formed at the gate terminal 38.

Namely, the titanium films 21a, 31a, and 41a, the aluminum films 21b, 31b and 41b, and the titanium films 21c, 31c and 41c are deposited respectively at the same time and configured to have predetermined shapes. In other words, the first conductive layers (the auxiliary capacitance line CS and the gate line G) are formed on the base material by performing the processes as shown in FIGS. 10A, 11A, 12A and 13A and subsequently the first conductive layer is patterned, thereby the gate electrode 18g of the thin film transistor 18 and the predetermined line (the auxiliary capacitance line CS and the gate electrode G) are formed, namely, a first step is finished.

The specific film thickness of the titanium films 21a, 31a and 41a and the titanium films 21c, 31c and 41c is in a range of 30 to 150 nm for example. The specific film thickness of the aluminum films 21b, 31b and 41b is in a range of 200 to 500 nm for example.

The materials of the above-mentioned titanium films 21a, 31a, and 41a, the aluminum films 21b, 31b and 41b, and the titanium films 21c, 31c and 41c can be replaced by metals such as molybdenum and copper, preferably a metal that can be wet-etched and less corrosive. For example, it can be a titanium film and an aluminum film, or a two-layered metal film of titanium and copper, or of molybdenum and copper.

Next, as indicated as step S2 in FIG. 9, the gate insulating film 22 and an island of the thin film transistor 18 is formed.

Specifically, as shown in FIG. 10B, the gate insulating film 22 made of silicon nitride (SiNx) is formed by the CVD method for example so as to cover the gate electrode 18g and the base material 5a. Further, an amorphous silicon layer 23 as the first semiconductor layer and an electrode contact layer 24 composed of an n+ amorphous silicon layer as the second semiconductor layer are formed sequentially by the CVD method for example on the gate insulating film 22. The gate insulating film 22, the amorphous silicon layer 23 and the electrode contact layer 24 are formed on the whole surface of the base material 5a. Namely, by performing the process of forming the gate insulating film 22, the amorphous silicon layer 23 and the electrode contact layer 24, the first insulating layer (the gate insulating film 22), the first semiconductor layer (the amorphous silicon layer 23) and the second semiconductor layer (the electrode contact layer 24) are formed sequentially to cover the gate electrode 18g and the above-mentioned electric line, namely, a second step is finished.

The specific film thickness of the gate insulating film 22 is in a range of 200 to 500 nm for example. The specific film thickness of the amorphous silicon layer 23 is in a range of 30 to 300 nm for example. The electrode contact layer 24 is doped with n-type impurities for example at a high concentration, and the specific film thickness is in a range of 50 to 150 nm for example. The temperature for depositing the gate insulating film 22, the amorphous silicon layer 23 and the electrode contact layer 24 is in a range of 200 to 300° C. for example.

Sequentially, using a halftone mask, an island composed of the amorphous silicon layer 23 and the electrode contact layer 24 as shown in FIG. 10B is formed in the thin film transistor 18, and at the same time, the opening portions H1 and H4 are formed at the connection portion 29 and the gate terminal 38 in the gate insulating film 22. Specifically, after forming the electrode contact layer 24 on the whole surface of the base material 5a, a half-tone mask having a three-level gradient resist pattern of no-resist, thin resist (resist-ham and thick resist (resist-full) is provided above the electrode contact layer 24. Here, the part of no-resist correspond to the part from which the gate insulating film 22, the amorphous silicon layer 23 and the electrode contact layer 24 are to be removed. The part of the resist-half corresponds to the part from which the amorphous silicon layer 23 and the electrode contact layer 24 are to be removed. At the part of resist-full, no layer is removed, but the gate insulating film 22, the amorphous silicon layer 23 and the electrode contact layer 24 remain.

More specifically, by carrying out the dry-etching, the gate insulating film 22, the amorphous silicon layer 23 and the electrode contact layer 24 are removed and as shown in FIGS. 11B and 13B respectively, the opening portions H1 and H4 are formed respectively at the connection portion 29 and at the gate terminal 38 in the gate insulating film 22. Further, by ashing, the resist is kept only at a thick part of the film, and subsequently by carrying out dry-etching, extra amorphous silicon layer and electrode contact layer are removed to form an island composed of the amorphous silicon layer 23 and the electrode contact layer 24 as shown in FIG. 10B.

Further, in the process of forming the opening portion H1, as shown in FIG. 11B, the end portion CS1 of the auxiliary capacitance line (first conductive layer) CS is provided to be exposed within the opening portion H1. Similarly, in the process of forming the opening portion H4, as shown in FIG. 13B, the end portion G1 of the gate line (first conductive layer) G is provided to be exposed within the opening portion H4. Thereby, even when the thickness of each of the first conductive layers mentioned above is reduced due to the developing solution, the peeling solution or the like in the photolithography process, a reliable connection to the corresponding second conductive layer as mentioned below is obtained. This is particularly favorable for a case of using a metal such as copper that will be corroded comparatively easily. In this manner, according to the present example, it is possible to configure a connection and terminals that have a reliable conductivity with various metal films.

By etching the first insulating layer (the gate insulating film 22), the first semiconductor layer (the amorphous silicon layer 23) and the second semiconductor layer (the electrode contact layer 24) during the above-mentioned processes, the semiconductor layer (the amorphous silicon layer 23) for the thin film transistor 18 and the electrode contact layer 24 are formed, and at the same time, in the first insulating layer (the gate insulating film 22), the opening portions H1, H4 are formed so as to expose the end portions of the electric lines (the auxiliary capacitance line CS and the gate line G), that is, the third step is finished. Further in this third step, since a half-tone mask having resists different from each other in the film thickness is used, the process can be simplified, and the time for producing the active matrix substrate 5 can be shortened easily.

Next, as indicated as step S3 in FIG. 9, the source electrode 18s and the channel region are formed.

Specifically, as shown in FIG. 10C, after depositing the titanium film 25a and the aluminum film 25b by applying the sputtering method for example, the films are patterned by carrying out photolithography, wet-etching, and resist-peeling washing, thereby forming the source electrode 18s composed of the titanium film 25a and the aluminum film 25b. Further, at the same of formation of this source electrode 18s, as shown in FIG. 10C, the drain electrode 18d composed of the titanium film 26a and the aluminum film 26b is formed. Further, by carrying out a dry-etching, the electrode contact layer 24 above the channel region is removed to form the electrode contact layers 24a, 24b, and also the channel region is formed.

Further, at the same time of formation of this source electrode 18s, as shown in FIG. 11C, the electrode member 30 as the second conductive layer composed of the titanium film 32a and the aluminum film 32b is formed at the connection portion 29 so as to cover at least a part of the edge of the opening portion H1 and also to be connected directly to the end portion CS1 of the auxiliary capacitance line CS within the opening portion H1. Further, at the same time of formation of this source electrode 18s, as shown in FIG. 12C, the electrode connection line 26 as the first conductive layer composed of the titanium film 26a and the aluminum film 26b is formed at the connection portion 34 on the gate insulating film 22. Further, at the same time of formation of this source electrode 18s, as shown in FIG. 13C, the titanium film 39 and the aluminum film 39′ to constitute the above-mentioned intermediate electrode member 39 as the second conductive layer are formed at the gate terminal 38 so as to cover at least a part of the edge of the opening portion H4 and also to be connected directly to the end portion G1 of the gate line G within the opening portion H4.

That is, the titanium films 25a, 26a, 32a, 39 and the aluminum films 25b, 26b, 32b, 39′ are deposited respectively at the same time, and configured to have predetermined shapes. In other words, by performing the processes as shown in FIGS. 10C, 11C, and 13C, the second conductive layers (the electrode member 30 and the intermediate electrode member 39) are formed to cover the semiconductor layer (the amorphous silicon layer 23), the electrode contact layer 24, and at least a part of the edges H1a, H4a of the opening portions H1, H4, and also to be connected directly to the end portions (CS1 and G1) of the electric lines (the auxiliary capacitance line CS and the gate line G) within the opening portions H1, H4. Namely, the fourth step is finished. Furthermore, the second conductive layers (the titanium films 25a, 26a and the aluminum films 25b, 26b) are patterned to form the source electrode 18s and the drain electrode 18d of the thin film transistor 18, namely, the fifth step is finished.

The specific film thickness of the titanium films 25a, 26a, 32a and 39 is in a range of 30 to 150 nm for example. The specific film thickness of the aluminum films 25b, 26b, 32b and 39′ is in a range of 100 to 400 nm for example.

It is also possible that the titanium films 25a, 26a, 32a, 39 and the aluminum films 25b, 26b, 32b, 39′ are replaced by films of metals such as molybdenum and copper, preferably a metal that can be wet-etched and less corrosive.

Further, the description above refers to a case where the intermediate electrode member 39 is provided at the gate terminal 38 so as to cover entirely the opening portion H4 of the gate insulating film 22 as shown in FIG. 3. However, the present embodiment is not limited to this example as long as at least a part of the opening portion H4 is covered with the intermediate electrode member 39 (this holds true for the source terminal 42).

Further at the moment that the above-mentioned fourth step is finished, the auxiliary capacitance line CS, the gate line G, and the source line S are to be connected respectively to the electrode member 30, the intermediate electrode members 39 and 43. Namely, the auxiliary capacitance CS, the gate line G, and the source line S will be brought into conduction with the corresponding electrode member 30, the intermediate electrode members 39 and 43, from an electrically-floating state in the initial stage of the processes for producing the active matrix substrate 5. As a result, in the active matrix substrate 5 of the present embodiment, occurrence of electrical breakdown in the auxiliary capacitance line CS, the gate line G, and the source line S can be reduced remarkably. And thus it is possible to improve remarkably the yield of the active matrix substrate 5.

Next, as shown as step S4 in FIG. 9, the protective layer 27 and the interlayer insulating film 28 are formed.

Specifically, as shown in FIG. 10D, the protective layer 27 made of silicon nitride (SiNx) is formed by the CVD method for example in order to cover the source electrode 18s and the drain electrode 18d. The specific thickness of this protective layer 27 is in a range of 100 to 700 nm. The temperature for depositing the protective layer 27 is in a range of 200 to 350° C. In general, for the purpose of preventing film-peeling or the like, it is deposited at lower temperature in comparison with the gate insulating film 22, the amorphous silicon layer 23, and the electrode contact layer 24. Next, a photosensitive interlayer insulating film material is applied by using a coater so as to have a thickness of 3 to 5 μm, thereby the interlayer insulating film 28 is formed. As mentioned above, by forming the protective layer 27 and the interlayer insulating film 28, the second insulating layers (the protective layer 27 and the interlayer insulating film 28) are formed to cover the source electrode 18s, the drain electrode 18d and the second conductive layers (the electrode member 30 and the intermediate electrode member 39), namely, the sixth step is finished.

At the time this sixth step is finished, as shown in FIG. 11D, the connection portion 29 is formed on the active matrix substrate 5.

Furthermore, the interlayer insulating film 28 is patterned by photolithography and then dry-etched, thereby the protective layer 27 and the interlayer insulating film 28 are patterned to have a predetermined shape. Thereby, the opening portions H5 and H6 are formed in the second insulating layers (the protective layer 27 and the interlayer insulating film 28) so as to expose the connection portion between the end portion (G1) of the electric line (the gate line G) and the second conductive layer (the intermediate electrode member 39). Namely, the seventh step is finished.

Specifically, as shown in FIG. 13D, the protective layer 27 is dry-etched at the gate terminal 38, so as to form the opening portion H5, and the interlayer insulating film 28 is dry-etched, so as to form the opening portion H6. Further, wet-etching is carried out at the gate terminal 38 so as to selectively etch only the aluminum, thereby removing the aluminum film 39′ exposed to the opening portion H5 (FIG. 13C). Thereby, the electrode member 40 formed of ITO to be deposited in a subsequent process is prevented from contacting with the aluminum film 39′ and thus corrosion in the electrode member 40 is prevented. This process is not necessary in a case of using copper, titanium, and molybdenum that are not corroded by the ITO.

Further, as shown in FIG. 12D, the protective layer 27 is dry-etched at the connection portion 34, so as to form the opening portion H2, and the interlayer insulating film 28 is dry-etched, so as to form the opening portion H3. At this connection portion 34, the titanium film 26a that is the end portion of the electrode connection line 26 as the first conductive layer is provided to be exposed within the opening portion H2. At this connection portion 34, similarly to the gate terminal 38, wet-etching is carried out to remove the aluminum film 26b exposed to the opening portion H2 (FIG. 12C). Thereby, the pixel electrode 19 formed of ITO to be deposited in a subsequent process is prevented from contacting with the aluminum film 26b and thus corrosion in the pixel electrode 19 is prevented.

Furthermore, in the process of forming the opening portion H5 and H6, as shown in FIG. 3, the connection portion between the end portion (G1) of the gate line G (the first conductive layer) and the intermediate electrode member (the second conductive layer) 39 is to be exposed within the opening portions H5 and H6. Thereby, even when the thickness of the second conductive layer is reduced due to the developing solution or the peeling solution and the like in the photolithography process, a reliable connection to the corresponding third conductive layer as mentioned below is obtained. This is particularly favorable for a case of using a metal such as copper that will be corroded comparatively easily.

Next, ITO is formed in the manner as shown as step S5 in FIG. 9.

Specifically, as shown in FIG. 10E, ITO of 50 to 200 nm is deposited with respect to the interlayer insulating film 28 by a sputtering method for example, which is then patterned by photolithography, wet-etching and resist-peeling washing, thereby the pixel electrode 19 is formed on the interlayer insulating film 28.

Further at the connection portion 34, as shown in FIG. 12E, the pixel electrode 19 as the second conductive layer is connected directly to the titanium film (the end portion of the first conductive layer) 26a within the opening portions H2, H3. Specifically, at this connection portion 34, the pixel electrode 19 is provided to cover at least a part of the edge H2a of the opening portion H2 of the protective layer 27 and at least a part of the edge H3a of the opening portion H3 of the interlayer insulating film 28, and also to be connected directly to the titanium film 26a within the opening portions H2, H3. Thereby, the connection portion 34 is provided on the active matrix substrate 5.

Further, as shown in FIG. 13E, the electrode member 40 as the third conductive layer is connected at the gate terminal 38 directly to the intermediate electrode member (the second conductive layer) 39 within the opening portions H5, H6. Specifically, at this gate terminal 38, the electrode member 40 is provided to cover at least a part of the edge H5a of the opening portion H5 of the protective layer 27 and at least a part of the edge H6a of the opening portion H6 of the interlayer insulating film 28, and also to be connected directly to the intermediate electrode member 39 within the opening portions H5, H6. Thereby, the third conductive layer (the electrode member 40) is formed to cover at least a part of each of the edges (H5a and H6a) of the opening portions (H5 and H6) of the second insulating layers (the protective layer 27 and the interlayer insulating film 28) and also to be connected directly to the second conductive layer (the intermediate electrode member 39) within the opening portions (H5, H6), namely, the eighth step is finished. Thereby, the gate terminal 38 is provided on the active matrix substrate 5.

In the thus configured active matrix substrate 5 of the present embodiment, the end portion CS1 of the auxiliary capacitance line (the first conductive layer) CS is provided at the connection portion 29 so as to protrude within the opening portion H1 formed in the gate insulating film (the first insulating layer) 22. Further, at the connection portion 29, the electrode member (the second conductive layer) 30 is provided to cover at least a part of the edge H1a of the opening portion H1 and also to be connected directly to the end portion CS1 of the auxiliary capacitance line CS within the opening portion H1. Thereby, it is possible to connect the electrode member 30 to the auxiliary capacitance line CS while preventing occurrence of disconnection in the electrode member 30.

Further, in the active matrix substrate 5 of the present embodiment, the end portion 26a of the electrode connection line (the first conductive layer) 26 is provided at the connection portion 34 so as to protrude within the opening portions H2 and H3 formed respectively in the protective layer 27 and the interlayer insulating film 28 (the insulating layers). Further, at the connection portion 34, the pixel electrode (the second conductive layer) 19 is provided to cover at least a part of each of the edges H2a, H3a of the opening portions H2, H3 and also to be connected directly to the end portion 26a of the electrode connection line 26 within the opening portions H2, H3. Thereby, it is possible to connect the pixel electrode 19 to the electrode connection line 26 while preventing occurrence of disconnection in the pixel electrode 19.

Further, in the active matrix substrate 5 of the present embodiment, the end portion G1 of the gate line (the first conductive layer) G is provided at the gate terminal 38 so as to protrude within the opening portion H4 formed in the gate insulating film (the first insulating layer) 22. Further, at the gate terminal 38, the intermediate electrode member (the second conductive layer) 39 is provided to cover at least a part of the edge H4a of the opening portion H4 and also to be connected directly to the end portion G1 of the gate line G within the opening portion H4. Thereby, it is possible to connect the intermediate electrode member 39 to the gate line G while preventing occurrence of disconnection in the intermediate electrode member 39. Further, at the gate terminal 38, the electrode member (the third conductive layer) 40 is provided to cover at least a part of each of the edges H5a and H6a of the opening portions H5 and H6, and also to be connected directly to the intermediate electrode member 39 within the opening portions H5, H6. Thereby, it is possible to connect the electrode member 40 to the intermediate electrode member 39 while preventing occurrence of disconnection in the electrode member 40.

Further, in the active matrix substrate 5 of the present embodiment, the end portion S1 of the source line (the first conductive layer) S is provided at the source terminal 42 so as to protrude within the opening portion H7 formed in the gate insulating film (the first insulating layer) 22. Further, at the source terminal 42, the intermediate electrode member (the second conductive layer) 43 is provided so as to cover at least a part of the edge H7a of the opening portion H7 and also to be connected directly to the end portion S1 of the source line S within the opening portion H7. Thereby, it is possible to connect the intermediate electrode member 43 to the source line S while preventing occurrence of disconnection in the intermediate electrode member 43. Further, at the source terminal 42, the electrode member (the third conductive layer) 44 is provided to cover at least a part of each of the edges H8a and H9a of the opening portions H8 and H9 and also to be connected directly to the intermediate electrode member 43 within the opening portions H8 and H9. Thereby, it is possible to connect the electrode member 44 to the intermediate electrode member 43 while preventing occurrence of disconnection in the electrode member 44.

As mentioned above, unlike the conventional examples, the active matrix substrate 5 where a plurality of conductive layers arranged with an insulating layer therebetween can be connected reliably to each other can be configured according to the present embodiment.

The above embodiments are shown for illustrative purposes and are not limiting. The technical range of the present invention is defined by the claims, and all the modifications within the range equivalent to the configuration recited in the claims are also included in the technical range of the present invention.

For example, in the above description, the present invention is applied to a transmission type liquid crystal display device. However, the active matrix substrate of the present invention is not particularly limited to this device but can be applied to various display panels such as a semi-transmission type or reflection type liquid crystal panel, an organic electronic luminescence (EL) element, an inorganic EL element, and a field emission display.

Further, the above description refers to a case of using as the first conductive layers an electrode connection line for connecting a drain electrode and the pixel electrode, an auxiliary capacitance line, a gate line and a source line, and using as the second conductive layers a pixel electrode, an electrode member for connecting the auxiliary capacitance line and a source driver (drive portion), an intermediate electrode member to be connected to the gate line, and an intermediate electrode member to be connected to the source line. However, the present invention is not limited particularly as long as the end portion of the first conductive layer is formed to protrude within the opening portion formed in the insulating layer and the second conductive layer is provided to cover at least a part of the edge of the opening portion and also to be connected directly to the end portion of the first conductive layer within the opening portion. Specifically, for example the above-mentioned common electrodes and the common electrode lines to be connected to the common electrodes can be used for the first conductive layer and for the second conductive layer vice versa.

Further, the above description refers to a case of using as the second conductive layers an intermediate electrode member to be connected to the gate line and an intermediate electrode member to be connected to the source line, and using as the third conductive layers an electrode member to be connected to the intermediate electrode member and to the gate driver and also an electrode member to be connected to the source driver. However, the present invention is not limited particularly as long as the second conductive layer is provided to cover at least a part of the edge of the opening portion formed in the first insulating layer and also to be connected directly to the end portion of the first conductive layer within the opening portion formed in the first insulating layer, and as long as the third conductive layer is provided to cover at least a part of the edge of the opening portion formed in the second insulating layer, and also to be connected directly to the second conductive layer within the opening portion formed in the second insulating layer.

The above description refers to a configuration of using a gate insulating film as the first insulating layer and using a protective layer and an interlayer insulating film as the second insulating layers. However, the first and second insulating layers of the present invention are not limited particularly to these examples as long as they are provided to cover respectively the first conductive layer and the second conductive layer. An alternative configuration of using only the protective layer as the second insulating layer is also applicable.

Further, the above description refers to a configuration of connecting the auxiliary capacitance line to the source driver (the drive portion). However, the present invention is not limited to this example. In an alternative configuration, the auxiliary capacitance line is connected to the gate driver as the drive portion, or to a drive portion (the driver) used exclusively for the auxiliary capacitance line so as to generate the auxiliary capacitance.

### INDUSTRIAL APPLICABILITY

The present invention is used favorably with regard to an active matrix substrate that allows a plurality of conductive layers arranged with an insulating layer therebetween to be connected to each other reliably, and a method for producing the same.

### EXPLANATION OF LETTERS AND NUMERALS

5 active matrix substrate

5a base material

16 source driver (drive portion)

17 gate driver

18 thin film transistor

18g gate electrode

18s source electrode

18d drain electrode

19 pixel electrode

22 gate insulating film (first insulating layer)

26 electrode connection line (first conductive layer)

26a end portion

27 protective layer (second insulating layer)

28 interlayer insulating film (second insulating layer)

30 electrode member (second conductive layer)

39 intermediate electrode member (second conductive layer)

40 electrode member (third conductive layer)

43 intermediate electrode member (second conductive layer)

44 electrode member (third conductive layer)

G gate line (first conductive layer, electric line)

G1 end portion

S source line (first conductive layer, electric line)

S1 end portion

CS auxiliary capacitance line (first conductive layer, electric line)

H1,H2,H3,H4,H5,H6,H7,H8,H9 opening portion

H1a,H2a,H3a,H4a,H5a,H6a,H7a,H8a,H9a edge (of opening portion)

1. An active matrix substrate having a first conductive layer and a second conductive layer to be connected to the first conductive layer, comprising at least one insulating layer provided to cover the first conductive layer,
wherein the first conductive layer has an end portion protruding within an opening portion formed in the insulating layer, and
the second conductive layer is provided to cover at least a part of the edge of the opening portion and to be connected directly to the end portion of the first conductive layer within the opening portion.

2. The active matrix substrate according to claim 1, comprising a thin film transistor and a pixel electrode to be connected to the thin film transistor,
wherein an electrode connection line to connect a drain electrode of the thin film transistor and the pixel electrode is used as the first conductive layer, and
the pixel electrode is used as the second conductive layer.

3. The active matrix substrate according to claim 1, comprising an auxiliary capacitance line for generating an auxiliary capacitance and a drive portion to be connected to the auxiliary capacitance line,
wherein the auxiliary capacitance line is used as the first conductive layer, and
an electrode member to connect the auxiliary capacitance line to the drive portion is used as the second conductive layer.

4. The active matrix substrate according to claim 1, comprising a third conductive layer to be connected to the second conductive layer,
wherein the insulating layer comprises a first insulating layer provided to cover the first conductive layer and a second insulating layer provided to cover the second conductive layer,
the first conductive layer has an end portion protruding within an opening portion formed in the first insulating layer,
the second conductive layer is provided to cover at least a part of the edge of the opening portion formed in the first insulating layer and to be connected directly to the end portion of the first conductive layer within the opening portion formed in the first insulating layer, and
the third conductive layer is provided to cover at least a part of the edge of an opening portion formed in the second insulating layer and to be connected directly to the second conductive layer within the opening portion formed in the second insulating layer.

5. The active matrix substrate according to claim 4, comprising a thin film transistor, a gate line to be connected to a gate electrode of the thin film transistor, and a gate driver to be connected to the gate line,
wherein the gate line is used as the first conductive layer,
an intermediate electrode member to be connected to the gate line is used as the second conductive layer, and
an electrode member to be connected to the intermediate electrode member and to the gate driver is used as the third conductive layer.

6. The active matrix substrate according to claim 4, comprising a thin film transistor, a source line to be connected to a source electrode of the thin film transistor, and a source driver to be connected to the source line,
wherein the source line is used as the first conductive layer,
an intermediate electrode member to be connected to the source line is used as the second conductive layer, and
an electrode member to be connected to the intermediate electrode member and to the source driver is used as the third conductor layer.

7. A method for producing an active matrix substrate having a first conductive layer and a second conductive layer to be connected to the first conductive layer, the method comprising:
a step of forming the first conductive layer;
a step of forming an insulating layer so as to cover the first conductive layer;
a step of forming an opening portion in the insulating layer by etching the insulating layer so that an end portion of the first conductive layer is exposed in the opening portion; and
a step of forming a second conductive layer so as to cover at least a part of the edge of the opening portion and to be connected directly to the end portion of the first conductive layer within the opening portion.

8. A method for producing an active matrix substrate comprising a thin film transistor and having a first conductive layer and a second conductive layer to be connected to the first conductive layer, the method comprising:
a first step of forming the first conductive layer on a base material and subsequently patterning the first conductive layer, so as to form a gate electrode of the thin film transistor and a predetermined electric line;
a second step of forming a first insulating layer, a first semiconductor layer and a second semiconductor layer sequentially so as to cover the gate electrode and the electric line;
a third step of forming a semiconductor layer and an electrode contact layer of the thin film transistor by etching the first insulating layer, the first semiconductor layer and the second semiconductor layer and also forming an opening portion in the first insulating layer so that an end portion of the electric line is exposed in the opening portion;
a fourth step of forming a second conductive layer so as to cover the semiconductor layer, the electrode contact layer and at least a part of the edge of the opening portion and to be connected directly to the end portion of the electric line within the opening portion; and
a fifth step of forming a source electrode and a drain electrode of the thin film transistor by patterning the second conductive layer.

9. The method for producing an active matrix substrate according to claim 8,
wherein an auxiliary capacitance line for generating an auxiliary capacitance is used as the electric line,
an electrode member to connect the auxiliary capacitance line and a drive portion to be connected to the auxiliary capacitance line is used as the second conductive layer, and
the fourth step is performed to form a connection portion between the auxiliary capacitance line and the electrode member.

10. The method for producing an active matrix substrate according to claim 8,
subsequent to the fifth step, comprising:
a sixth step of forming a second insulating layer so as to cover the source electrode, the drain electrode and the second conductive layer;
a seventh step of forming an opening portion in the second insulating layer so that a connection portion between the end portion of the electric line and the second conductive layer is exposed in the opening portion; and
an eighth step of forming a third conductive layer so as to cover at least a part of the edge of the opening portion of the second insulating layer and to be connected directly to the second conductive layer within the opening portion.

11. The method for producing an active matrix substrate according to claim 10,
wherein a gate line to be connected to the gate electrode of the thin film transistor is used as the electric line,
an intermediate electrode member to be connected to the gate line is used as the second conductive layer,
an electrode member to be connected to a gate driver and to the intermediate electrode member is used as the third conductive layer, and
the eighth step is performed to form a gate terminal for connecting the gate line and the gate driver.

12. The method for producing an active matrix substrate according to claim 10,
wherein a source line to be connected to the source electrode of the thin film transistor is used as the electric line,
an intermediate electrode member to be connected to the source line is used as the second conductive layer,
an electrode member to be connected to a source driver and to the intermediate electrode member is used as the third conductive layer, and
the eighth step is performed to form a source terminal for connecting the source line and the source driver.

13. The method for producing an active matrix substrate according to claim 10,
wherein an electrode connection line for connecting the drain electrode of the thin film transistor and a pixel electrode to be connected to the thin film transistor is formed by using the second conductive layer that has been formed in the fourth step, and
the pixel electrode is formed by use of the third conductive layer formed in the eighth step, and the eighth step is performed to form a connection portion between the electrode connection line and the pixel electrode.

14. The method for producing an active matrix substrate according to claim 8,
wherein a halftone mask having resists different from each other in the film thickness is used in the third step1
